(19) United States
(12) Patent Application Publication
(10) Pub. No.: US 2025/0391486 A1
(43) Pub. Date: Dec. 25, 2025

(54) ONE-TIME PROGRAMMABLE (OTP) MEMORY SUPPORTING FABRICATED ICS IN DIFFERENT DESIGN CONFIGURATIONS

(71) Applicant: Shaoxing Yuanfang Semiconductor Co., Ltd., Shaoxing (CN)

(72) Inventors: Michael Figueiredo, Amora (PT); Arnold J D'Souza, Bangalore (IN); Shyam Somayajula, Bangalore (IN); Yunsong Wang, Shanghai (CN)

(21) Appl. No.: 18/926,386

(22) Filed: Oct. 25, 2024

(30) Foreign Application Priority Data
Jun. 25, 2024 (IN) 202441048734

(51) Int. Cl. G11C 17/18

(52) U.S. Cl. CPC G11C 17/18

(57) ABSTRACT

According to an aspect of the present disclosure, an (fabricated) integrated circuit (IC) comprises a one-time programmable (OTP) memory storing multiple bits, multiple functional circuits and a decoder circuit operable to read, from the OTP memory, a set of bits and determine a first design configuration based on a subset of the set of bits. Each design configuration corresponds to a scenario of usage of the IC and specifies a respective convention on usage of a rest of the set of bits for corresponding features to be realized based on one or more of the functional circuits. The decoder circuit then operates a set of functional circuits to realize a first set of features indicated by the rest of the set of bits according to the respective convention corresponding to the first design configuration.

### PRIORITY CLAIM

The instant patent application is related to and claims priority from the co-pending provisional India patent application entitled, “EFUSE REUSE”, Serial No.: 202441048734, Filed: 25 June 2024; Attorney docket no.: AURA-362-INPR, which is incorporated in its entirety herewith to the extent not inconsistent with the description herein.

### BACKGROUND

### Technical Field

Embodiments of the present disclosure relate generally to design of integrated circuits, and more specifically to one-time programmable (OTP) memory supporting fabricated ICs in different design configurations.

### Related Art

Design life cycle in semi-conductor industry generally involves designing a desired circuit using various computer aided design (CAD) tools, generating mask works for the designed circuit, and sending the mask-works for fabrication. Many integrated circuits (ICs) are fabricated based on the same mask-works, as is also well known in the relevant arts. In general, any redesign and further fabrication of the desired circuit is an expensive process.

ICs thus fabricated may need to be used differently in different scenarios. For example, some portions of the designed circuit may need to be operated a specific way (e.g., enabled or disabled) for testing purpose, while some other portions may need to be operated differently during production. In addition, different customers may have different requirements for their specific purpose, for example, when sampling the fabricated ICs.

Each fabricated IC may accordingly need to be configured to meet the requirements of the corresponding scenario of usage. Such configuration is operative at the time of powering-up of the IC and accordingly the IC is said to have the corresponding design configuration.

One-Time Programmable (OTP) memory is often used to specify such design configurations operative for individual ones of the fabricated ICs. In general, different values in different bit positions together indicate the corresponding design configuration.

Aspects of the present disclosure are directed to one-time programmable (OTP) memory supporting fabricated ICs in different design configurations.

### BRIEF DESCRIPTION OF THE VIEWS OF DRAWINGS

Example embodiments of the present disclosure will be described with reference to the accompanying drawings briefly described below.

FIG. 1A is a block diagram illustrating a logical view of an integrated circuit (IC) in a prior embodiment.

FIG. 1B is a block diagram illustrating the manner in which a controller operates based on an OTP memory in one prior embodiment.

FIG. 2 is a block diagram of an example IC in which several aspects of the present disclosure can be implemented.

FIG. 3 is a flow chart illustrating the manner in which an OTP memory supporting fabricated ICs in different design configurations is implemented according to aspects of the present disclosure.

FIG. 4 is a table illustrating the manner in which an OTP memory supporting fabricated ICs in different design configurations is provided in one embodiment.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

According to an aspect of the present disclosure, an (fabricated) integrated circuit (IC) comprises a one-time programmable (OTP) memory storing multiple bits, multiple functional circuits and a decoder circuit. The decoder circuit is operable to read a set of bits from the OTP memory, and determine a specific design configuration based on a subset of the set of bits. Each design configuration corresponds to a scenario of usage of the IC and specifies a respective convention on usage of a rest of the set of bits for corresponding features to be realized based on one or more of the functional circuits. The decoder circuit then operates a set of functional circuits to realize a first set of features indicated by the rest of the set of bits according to the respective convention corresponding to the specific design configuration.

Thus, the rest of the set of bits is used according to one convention in a first design configuration (suited for one scenario of usage) and the same bits are then reused according to another convention in a second design configuration (as suited for a different scenario of usage).

According to another aspect of the present disclosure, when the subset of the set of bits equals a first value, a first set of bits of the rest of the set of bits indicates whether or not to enable a first functional circuit. The decoder circuit accordingly enables the first functional circuit if the first set of bits indicate that the first functional circuit is to be enabled and does not enable the first functional circuit otherwise. In one embodiment, the first value for the subset of the set of bits indicates that the scenario of usage of the IC is a testing scenario.

According to one more aspect of the present disclosure, when the subset of the set of bits equals a second value, a second set of bits of the rest of the set of bits indicates a specific frequency at which a second functional circuit is to be operated. The decoder circuit accordingly configures the second functional circuit to operate at the specific frequency.

In one embodiment, the second set of bits is set to a first value if shipped to a first customer and to a second value if shipped to a second customer to cause the second functional circuit to be operative with a first frequency for the first customer and with a second frequency for the second customer. As such, the second value for the subset of the set of bits indicates that the scenario of usage of the IC is a customer sampling scenario.

According to yet another aspect of the present disclosure, when the subset equals a third value, a third set of bits of the rest of the set of bits indicates an identifier of a die/wafer on which the IC is fabricated. In one embodiment, the third value for the subset of the set of bits indicates that the scenario of usage of the IC is a production scenario.

Several aspects of the present disclosure are described below with reference to examples for illustration. However, one skilled in the relevant art will recognize that the disclosure can be practiced without one or more of the specific details or with other methods, components, materials and so forth. In other instances, well-known structures, materials, or operations are not shown in detail to avoid obscuring the features of the disclosure. Furthermore, the features/aspects described can be practiced in various combinations, though only some of the combinations are described herein for conciseness.

### 2. Example Prior System

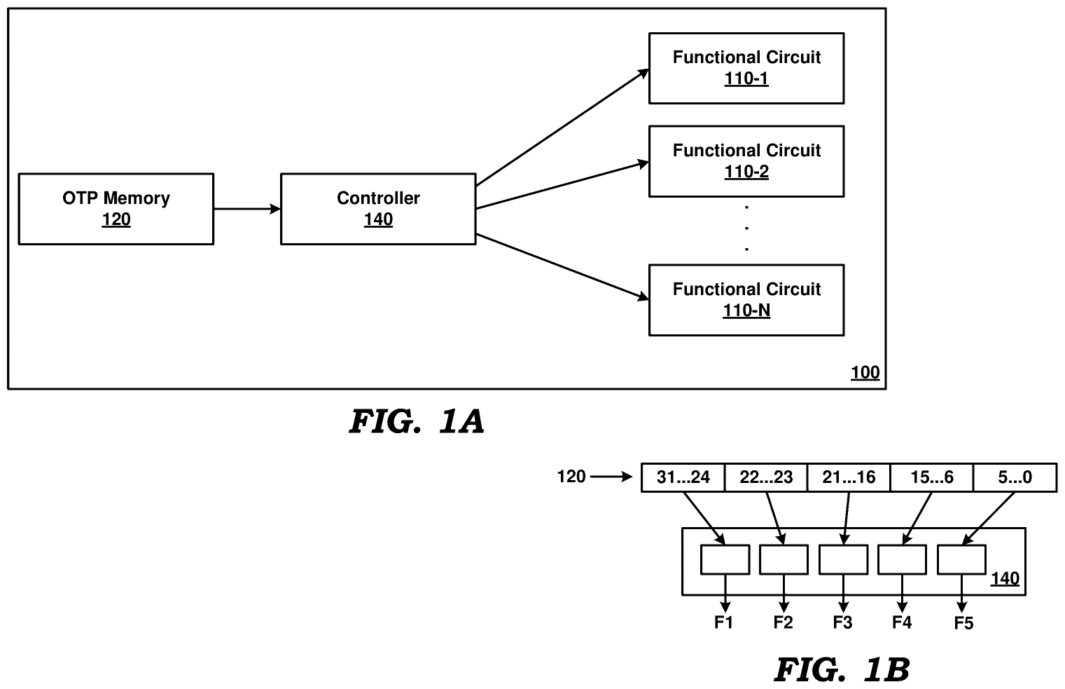

FIG. 1A is a block diagram illustrating a logical view of an integrated circuit (IC) in a prior embodiment. IC 100 is shown containing functional circuits 110-1 to 110-N (N representing any natural number), one-time programmable (OTP) memory 120 and controller 140. The functional circuits are collectively referred to by 110. It is understood that IC 100 can contain more or fewer blocks than those shown in FIG. 1A.

In an embodiment, the IC is fabricated as a single unit, with the blocks of FIG. 1A and their interconnections (not shown) built up on a substrate of semiconductor material (typically silicon). Multiple ICs are typically fabricated on a single substrate, commonly referred to as a wafer, with each IC referred to as a die/chip. Each of the blocks of FIG. 1A is described in detail below.

Each of functional circuits 110 represents a collection of electronic components (such as transistors, diodes, resistors, capacitors, connectors, etc.) that together operate to implement a functionality of IC 100. Each functional circuit may implement a complex function (e.g., a processor or a logic block) or provide specific functions to operate, for example as, amplifiers, high-pass/low-pass filters, voltage invertors, voltage regulators, voltage-controlled oscillators (VCO), A/D converters, etc.

OTP memory 120 represents a memory containing one or more bits (typically 16 or 32), with each bit being set (programmed) to a desired value (0 or 1) only once. OTP memory 120 is typically programmed after fabrication/manufacturing of the IC. Once programmed, or blown, the content (values of the bits) of OTP memory 120 cannot be changed and the content is retained after power is removed. This is in contrast to ROM (read-only memory) where the content is set at design/manufacturing time, and PROM (programmable read-only memory) where the content can be modified multiple times after manufacturing. In one embodiment, OTP memory 120 is implemented using a bank of eFuses well known in the arts, with each eFuse representing a bit.

Controller 140 represents a circuit that operates to read the content of OTP memory 120 and controls the operation of one or more of functional circuits 110. The operation of controller 140 is described in detail below.

FIG. 1B is a block diagram illustrating the manner in which a controller (140) operates based on an OTP memory (120) in one prior embodiment. OTP 120 is shown containing 32 bits, which are grouped into one or more groups (0 . . . 5, 6 . . . 15, etc.). Controller 140 reads each group of bits individually and realizes a corresponding feature (one or F1 to F5) based on the values of the group of bits.

Each of features F1 to F5 represents a desired behavior/characteristic sought to be realized using one or more of functional circuits 110. The desired behavior/characteristic may be one of enabling/not enabling a functional circuit, configuring a functional circuit to operate at a specific frequency, indicating an identifier of a die/wafer on which the IC (100) is fabricated, etc. In general, controller 140 sends one or more signals to functional circuits 110 to realize desired one or more features (F1 to F5) as indicated by the content of OTP 120.

It may be appreciated that the above noted usage of OTP memory allows programming a device (IC) for multiple setups. OTP memory may allow having one chip supporting multiple platforms (each with different design configuration) by programming a specific set of bits for each platform, useful to save calibration information which is specific for each device, used to save any type of die version/identification or wafer coordinate information, used to set up the chip for test/debug mode and a different setup for production.

However, the as the complexity of the chip increases, the number of OTP bits has to be increased to provide the increasing programming capability and options. Such increase in the number of OTP bits comes at the cost of die area because each OTP bit (eFuse cell) occupies space on the die. In addition, the complexity in the implementation of controller 140 also increases to handle the additional routing required for the increased programming capability.

Aspects of the present disclosure are directed to reusing some of the existing bits in OTP memory (120) for different purposes without increasing the die area, effectively increasing the number of bits. Specifically, as described above in the Background section, aspects are directed to an OTP memory supporting fabricated ICs in different design configurations, as described below with examples.

### 3. Novel IC

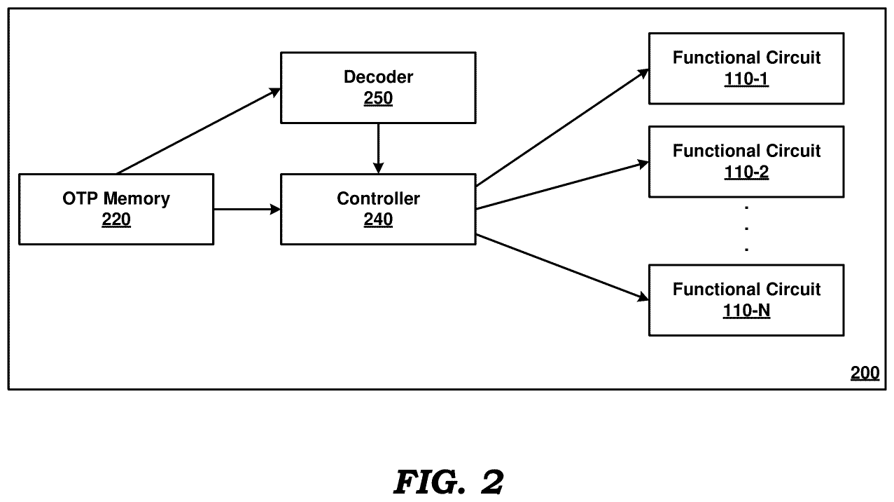

FIG. 2 is a block diagram of an example IC in which several aspects of the present disclosure can be implemented. IC 200 is shown containing functional circuits 110-1 to 110-N (N representing any natural number), one-time programmable (OTP) memory 220, controller 240 and decoder 250. It is understood that IC 200 can contain more or fewer blocks than those shown in FIG. 2.

OTP memory 220 is similar to OTP 120, but stores bits according to aspects of the present disclosure. Controller 240, similar to controller 140, represents a circuit that operates to read the content of OTP memory 220 and controls the operation of one or more of functional circuits 110.

Decoder circuit 250, provided according to several aspects of the present disclosure, facilitates the reuse of some of the existing bits in OTP memory (120) for different purposes, as described below with examples.

### 4. OTP Memory Supporting Fabricated ICs in Different Design Configurations

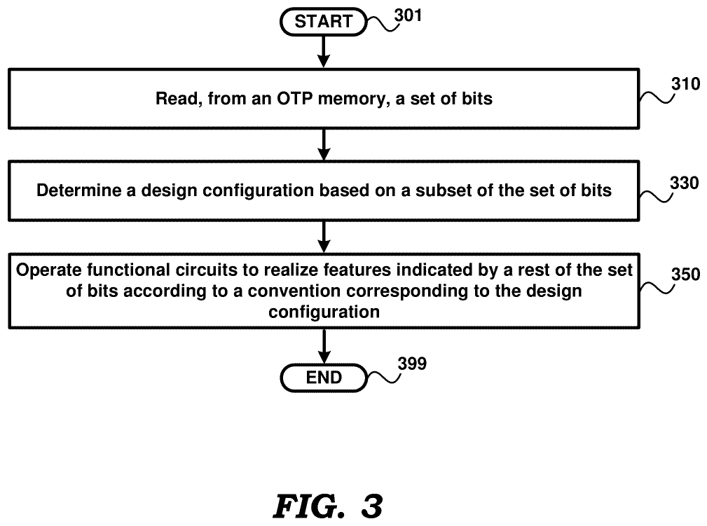

FIG. 3 is a flow chart illustrating the manner in which an OTP memory supporting fabricated ICs in different design configurations is implemented according to aspects of the present disclosure. The flowchart is described with respect to the blocks of FIG. 2 in particular decoder circuit 250, merely for illustration. However, many of the features can be implemented in other environments also without departing from the scope and spirit of several aspects of the present invention, as will be apparent to one skilled in the relevant arts by reading the disclosure provided herein.

In addition, some of the steps may be performed in a different sequence than that depicted below, as suited to the specific environment, as will be apparent to one skilled in the relevant arts. Many of such implementations are contemplated to be covered by several aspects of the present invention. The flow chart begins in step 301, in which control immediately passes to step 310.

In step 310, decoder circuit 250 reads, from an OTP memory (220), a set of bits. For simplicity it is assumed that the set of bits correspond to all the bits stored in OTP Memory, even though only some of such stored bits may be used in accordance with the features of the present disclosure.

In step 330, decoder circuit 250 determines a design configuration based on a subset of the set of bits (referred hereinafter to as “switcher” bits). The switcher bits may be a single bit or multi-bit. In general, the subset contains bits less than the number of bits in the set of bits. Assuming for example that OTP memory contains only 8 bits, the switcher bits may be 1 bit of the 8 bits.

As described above, IC 200 (IC) may be required to be operate in different design configurations. Each design configuration corresponds to a scenario of usage of the IC and specifies a respective convention on usage of a rest of the set of bits (in the above example, 8−1=7 bits) for corresponding features to be realized based on one or more of functional circuits 110.

In step 350, decoder circuit 250 operates functional circuits (110) to realize one or more features indicated by a rest of the set of bits (referred hereinafter to as “data” bits) according to a convention corresponding to the design configuration. Control then passes to step 399, where the flow chart ends.

Thus, an OTP memory supporting fabricated ICs in different design configurations is provided. The manner in which several aspects of the present disclosure are provided according to the steps of FIG. 3 is described below with examples.

### 5. Illustrative Example

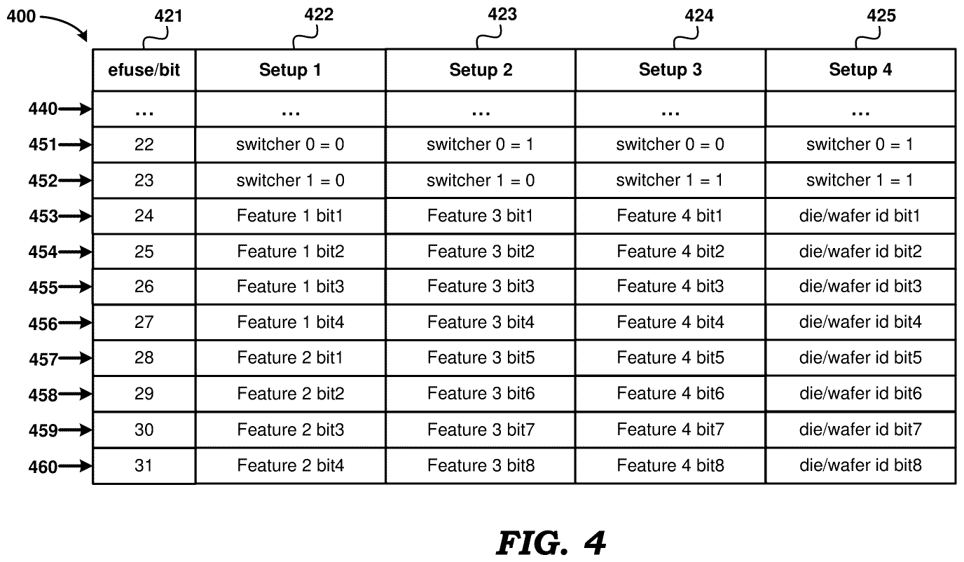

FIG. 4 is a table illustrating the manner in which an OTP memory supporting fabricated ICs in different design configurations is provided in one embodiment. Specifically, table 400 indicates a 32-bit OTP memory, where the last 8 bits (data bits 24-31) have different purpose depending on the value indicated by switcher bits 22 and 23. Such a design may be desirable where multiple features are required to go through the process of test/debug scenario, multiple customer sampling (assuming 2 customers) scenario and production scenario. As there are 3 values to be specified corresponding to the 3 scenarios, the number of switcher bits is selected to be 2.

Column 421 indicates the eFuse/bit number in the OTP memory (220). Row 440 corresponds to the value of bits 0 . . . 21, which realize features that are common across all the design configurations (when applicable). Rows 451 and 452 indicates the values of the 2 switcher bits (bit no. 22 and 23) in different design configurations (in the corresponding columns), while rows 453-460 indicate the values of the 8 data bits (bit no. 24 through 31) according to the convention for the corresponding design configuration (setup).

Each of columns 422 to 425 specifies a corresponding setup of the switcher and data bits. Column 422 specifies a Setup 1, where the switcher bits are set to value 0 (bits “00”), with some of the data bits (e.g., bit no. 24 through 27) indicating data corresponding to a Feature 1 (such as whether to enable or not enable a functional circuit). Other data bits are shown indicating data corresponding to a different Feature 2. It may be appreciated that Setup 1 may correspond to a testing scenario, with decoder circuit 250 enabling or not enabling the functional circuit based on data bits 24 through 27.

Column 423 specifies a Setup 2, where the switcher bits are set to value 1 (bits “01”), with some of the data bits (e.g., bit no. 24 through 31) indicating data corresponding to a Feature 3 (such as a specific frequency at which a functional circuit is to be operated). It may be appreciated that Setup 2 may correspond to a customer sampling scenario, with the data bits indicating a specific frequency at which a VCO (one of the functional circuits 110) is to be operated. Decoder circuit 250 may accordingly configure the VCO to operate at the specific frequency, for example, a first frequency (8 MHz) for a first customer and with a second frequency (10 MHz) for a second customer.

Column 424 specifies a Setup 3, where the switcher bits are set to value 2 (bits “10”), with some of the data bits (e.g., bit no. 24 through 31) indicating data corresponding to a Feature 4. It may be appreciated that Setups 2 and 3 may also be used in a customer sampling scenario. For example, Setup 2 may be sent to a first customer such that data bits 24-31 will act only on Feature 3, while Setup 3 may be sent to a second customer such that data bits 24-31 will act only on Feature 4.

Column 425 specifies a Setup 4, where the switcher bits are set to value 3 (bits “11”), with some of the data bits (e.g., bit no. 24 through 31) indicating an identifier of a die/wafer on which the IC is fabricated. As is well known, the die/wafer identifier may be used to identify the specific IC when troubleshooting any issue with the fabrication. It may be appreciated that Setup 4 may correspond to a production scenario.

Thus, decoder circuit 250 may read the switcher bits during powerup and decide what to do with the data bits. In the above example, if switcher bits are set to 3, decoder circuit 250 reads die/wafer id bits and provide the bits upon enquiry. If the switcher bits are set to other values, decoder circuit 250 reads the data bits and appropriately configures the functional circuits (110) to realize the desired features for that scenario/design configuration.

Accordingly, many ICs may be fabricated based on the same maskworks, and the OTP memory may be suitably burnt/set/blown according to the specific scenario of usage of the individual ICs. Such an objective is met by reuse of the bits (data bits) without physically increasing the number of bits in the OTP memory.

### 6. Conclusion

References throughout this specification to “one embodiment”, “an embodiment”, or similar language means that a particular feature, structure, or characteristic described in connection with the embodiment is included in at least one embodiment of the present disclosure. Thus, appearances of the phrases “in one embodiment”, “in an embodiment” and similar language throughout this specification may, but do not necessarily, all refer to the same embodiment.

While in the illustrations of the Figures, although terminals/nodes are shown with direct connections to (i.e., “connected to”) various other terminals, it should be appreciated that additional components (as suited for the specific environment) may also be present in the path, and accordingly the connections may be viewed as being “electrically coupled” to the same connected terminals.

It should be appreciated that the specific type of transistors (such as NMOS, PMOS, etc.) noted above are merely by way of illustration. However, alternative embodiments using different configurations and transistors will be apparent to one skilled in the relevant arts by reading the disclosure provided herein. For example, the NMOS transistors may be replaced with PMOS (P-type MOS) transistors, while also interchanging the connections to power and ground terminals.

Accordingly, in the instant application, the power and ground terminals are referred to as constant reference potentials, the source (emitter) and drain (collector) terminals of transistors (though which a current path is provided when turned on and an open path is provided when turned off) are termed as current terminals, and the gate (base) terminal is termed as a control terminal.

While various embodiments of the present disclosure have been described above, it should be understood that they have been presented by way of example only, and not limitation. Thus, the breadth and scope of the present disclosure should not be limited by any of the above-described embodiments, but should be defined only in accordance with the following claims and their equivalents.

Further, the purpose of the following Abstract is to enable the Patent Office and the public generally, and especially the scientists, engineers and practitioners in the art who are not familiar with patent or legal terms or phraseology, to determine quickly from a cursory inspection the nature and essence of the technical disclosure of the application. The Abstract is not intended to be limiting as to the scope of the present disclosure in any way.

What is claimed is:

1. A integrated circuit (IC) comprising:
a one-time programmable (OTP) memory storing a plurality of bits;
a plurality of functional circuits;
a decoder circuit operable to:
read, from said OTP memory, a set of bits of said plurality of bits;
determine a first design configuration of a plurality of design configurations based on a subset of said set of bits, wherein each design configuration of said plurality of design configurations corresponds to a scenario of usage of said IC and specifies a respective convention on usage of a rest of said set of bits for corresponding features to be realized based on one or more of said plurality of functional circuits; and
operate a set of functional circuits of said plurality of functional circuits to realize a first set of features indicated by said rest of said set of bits according to said respective convention corresponding to said first design configuration.

2. The IC of claim 1, wherein when said subset of said set of bits equals a first value, a first set of bits of said rest of said set of bits indicates whether or not to enable a first functional circuit of said plurality of functional circuits,
wherein said decoder circuit enables said first functional circuit if said first set of bits indicate that said first functional circuit is to be enabled and does not enable said first functional circuit otherwise.

3. The IC of claim 2, wherein said first value for said subset of said set of bits indicates that said scenario of usage of said IC is a testing scenario.

4. The IC of claim 2, wherein when said subset of said set of bits equals a second value, a second set of bits of said rest of said set of bits indicates a specific frequency at which a second functional circuit of said plurality of functional circuits is to be operated,
wherein said decoder circuit configures said second functional circuit to operate at said specific frequency.

5. The IC of claim 4, wherein said second set of bits is set to a first value if shipped to a first customer and to a second value if shipped to a second customer to cause said second functional circuit to be operative with a first frequency for said first customer and with a second frequency for said second customer,
wherein said second value for said subset of said set of bits indicates that said scenario of usage of said IC is a customer sampling scenario.

6. The IC of claim 4, wherein when said subset equals a third value, a third set of bits of said rest of said set of bits indicates an identifier of a die/wafer on which said IC is fabricated.

7. The IC of claim 6, wherein said third value for said subset of said set of bits indicates that said scenario of usage of said IC is a production scenario.

8. A decoder circuit operative in an integrated circuit (IC), the decoder circuit operable to:
read, from a one-time programmable (OTP) memory contained in said IC, a set of bits;
determine a first design configuration of a plurality of design configurations based on a subset of said set of bits, wherein each design configuration of said plurality of design configurations corresponds to a scenario of usage of said IC and specifies a respective convention on usage of a rest of said set of bits for corresponding features to be realized based on one or more of a plurality of functional circuits contained in said IC; and
operate a set of functional circuits of said plurality of functional circuits to realize a first set of features indicated by said rest of said set of bits according to said respective convention corresponding to said first design configuration.

9. The decoder circuit of claim 8, wherein when said subset of said set of bits equals a first value, a first set of bits of said rest of said set of bits indicates whether or not to enable a first functional circuit of said plurality of functional circuits,
said decoder circuit further operable to enable said first functional circuit if said first set of bits indicate that said first functional circuit is to be enabled and does not enable said first functional circuit otherwise.

10. The decoder circuit of claim 9, wherein said first value for said subset of said set of bits indicates that said scenario of usage of said IC is a testing scenario.

11. The decoder circuit of claim 9, wherein when said subset of said set of bits equals a second value, a second set of bits of said rest of said set of bits indicates a specific frequency at which a second functional circuit of said plurality of functional circuits is to be operated,
said decoder circuit further operable to configure said second functional circuit to operate at said specific frequency.

12. The decode circuit of claim 11, wherein said second set of bits is set to a first value if shipped to a first customer and to a second value if shipped to a second customer to cause said second functional circuit to be operative with a first frequency for said first customer and with a second frequency for said second customer,
wherein said second value for said subset of said set of bits indicates that said scenario of usage of said IC is a customer sampling scenario.

13. The decoder circuit of claim 11, wherein when said subset equals a third value, a third set of bits of said rest of said set of bits indicates an identifier of a die/wafer on which said IC is fabricated.

14. The decoder circuit of claim 13, wherein said third value for said subset of said set of bits indicates that said scenario of usage of said IC is a production scenario.

15. A method implemented in an integrated chip (IC), the method comprising:
reading, from a one-time programmable (OTP) memory contained in said IC, a set of bits;
determining a first design configuration of a plurality of design configurations based on a subset of said set of bits, wherein each design configuration of said plurality of design configurations corresponds to a scenario of usage of said IC and specifies a respective convention on usage of a rest of said set of bits for corresponding features to be realized based on one or more of a plurality of functional circuits contained in said IC; and
operating a set of functional circuits of said plurality of functional circuits to realize a first set of features indicated by said rest of said set of bits according to said respective convention corresponding to said first design configuration.

16. The method of claim 15, wherein when said subset of said set of bits equals a first value, a first set of bits of said rest of said set of bits indicates whether or not to enable a first functional circuit of said plurality of functional circuits,
said method further comprising enabling said first functional circuit if said first set of bits indicate that said first functional circuit is to be enabled and does not enable said first functional circuit otherwise.

17. The method of claim 16, wherein said first value for said subset of said set of bits indicates that said scenario of usage of said IC is a testing scenario.

18. The method of claim 16, wherein when said subset of said set of bits equals a second value, a second set of bits of said rest of said set of bits indicates a specific frequency at which a second functional circuit of said plurality of functional circuits is to be operated,
said method further comprising configuring said second functional circuit to operate at said specific frequency.

19. The method of claim 18, wherein said second set of bits is set to a first value if shipped to a first customer and to a second value if shipped to a second customer to cause said second functional circuit to be operative with a first frequency for said first customer and with a second frequency for said second customer,
wherein said second value for said subset of said set of bits indicates that said scenario of usage of said IC is a customer sampling scenario.

20. The method of claim 18, wherein when said subset equals a third value, a third set of bits of said rest of said set of bits indicates an identifier of a die/wafer on which said IC is fabricated,
wherein said third value for said subset of said set of bits indicates that said scenario of usage of said IC is a production scenario.
